(19) United States
(12) Patent Application Publication
(10) Pub. No.: US 2024/0274574 A1
(43) Pub. Date: Aug. 15, 2024

(54) CHIP PACKAGING METHOD AND CHIP PACKAGE BASED ON PANEL FORM

(71) Applicant: SAMSUNG ELECTRONICS CO., LTD., Suwon-si (KR)

(72) Inventor: Peng ZHANG, Suzhou Industrial Park (CN)

(73) Assignee: SAMSUNG ELECTRONICS CO., LTD., Suwon-si (KR)

(21) Appl. No.: 18/396,340

(22) Filed: Dec. 26, 2023

(30) Foreign Application Priority Data
Feb. 10, 2023 (CN) 202310096366.2

(51) Int. Cl. H01L 25/065; H01L 23/00; H01L 23/31; H01L 23/498

(52) U.S. Cl. CPC H01L 25/0652; H01L 23/3128; H01L 23/49816; H01L 24/05; H01L 24/13; H01L 2224/05009; H01L 2224/05025; H01L 2224/13009; H01L 2224/13025; H01L 2924/15311; H01L 2924/182

(57) ABSTRACT

A chip packaging method and a chip package based on a panel form are provided. The chip packaging method includes: preparing a plurality of chip package units, each of the plurality of chip package units having a panel form and including a plurality of dies; sequentially stacking the plurality of chip package units on a substrate, and using a thermal compression bonding process to electrically connect the plurality of chip package units to each other and electrically connect the plurality of chip package units and the substrate to each other, to obtain a stack; and cutting the stack to form single packages.

### CROSS-REFERENCE TO RELATED APPLICATION

This application is based on and claims priority under 35 U.S.C. § 119 to the Chinese Patent Application No. 202310096366.2, filed on Feb. 10, 2023, in the China National Intellectual Property Administration, the disclosure of which is incorporated by reference herein in its entirety.

### BACKGROUND

### 1. Field

Example embodiments of the present disclosure relate to the field of semiconductor packages, and in particular, to a chip packaging method and a chip package based on a panel form.

### 2. Description of the Related Art

Generally, in order to achieve stacking of through-silicon-via (TSV) chips, the related art uses a thermal compression bonding (TCB) method to conduct a signal interconnection between a single chip and a printed circuit board (PCB), and then uses an epoxy molding compound (EMC), e.g., an epoxy resin, to package stacked TSV chips.

FIG. 1 illustrates a chip packaging method according to related art. Referring to FIG. 1, a plurality of chips 20 are stacked on a PCB 10 by using a TCB method. Next, the plurality of chips 20 and the PCB 10 are electrically connected to each other. Finally, a stack including the plurality of chips 20 is packaged by using an EMC 30. This method of using a chip-to-chip TCB is disadvantageous in that a production efficiency is low due to a long bonding time; a defect of a non-conductive film (NFC) fillet is easily caused by the chip-to-chip bonding process; and a defect of a chipping is easily caused by a thin TSV chip in a cutting process.

The above information described in this Background section is only for enhancing the understanding of the background of the present disclosure, and is not an admission of prior art.

### SUMMARY

According to embodiments of the present disclosure, a chip packaging method and a chip package based on a panel form for improving a yield of a semiconductor packaging process is provided.

According to embodiments of the present disclosure, a chip packaging method is provided. The chip packaging method includes: preparing a plurality of chip package units, each of the plurality of chip package units having a panel form and including a plurality of dies; sequentially stacking the plurality of chip package units on a substrate, and using a thermal compression bonding process to electrically connect the plurality of chip package units to each other and electrically connect the plurality of chip package units and the substrate to each other, to obtain a stack; and cutting the stack to form single packages.

According to embodiments of the present disclosure, a chip package is provided. The chip package includes: a substrate; and a plurality of chip package units sequentially stacked on the substrate, each of the plurality of chip package units having a panel form. Each chip package unit from among the plurality of chip package units includes: a carrier; a plurality of dies mounted on the carrier; and an encapsulation layer formed of a molding material, the encapsulation layer at least covering side surfaces of each of the plurality of dies, and wherein the plurality of chip package units are electrically connected to each other and are electrically connected to the substrate by a thermal compression bonding process.

According to embodiments of the present disclosure, a method of preparing a chip package unit is provided. The method of preparing a chip package unit includes: scribing an original wafer to obtain a plurality of dies; mounting the plurality of dies on a carrier, and using a molding material to encapsulate the plurality of dies that are mounted on the carrier, to obtain an encapsulator; thinning the encapsulator to obtain a preliminary chip package unit, the preliminary chip package unit having a panel form; and obtaining the chip package unit, the obtaining including forming an electrical connection component on the preliminary chip package unit.

### BRIEF DESCRIPTION OF DRAWINGS

Features and advantages of the above and other aspects of the present disclosure will become apparent from the following detailed description of non-limiting example embodiments thereof, taken in conjunction with the accompanying drawings. In the drawings, like reference numerals will denote like elements throughout.

FIG. 1 illustrates a chip packaging method according to the related art.

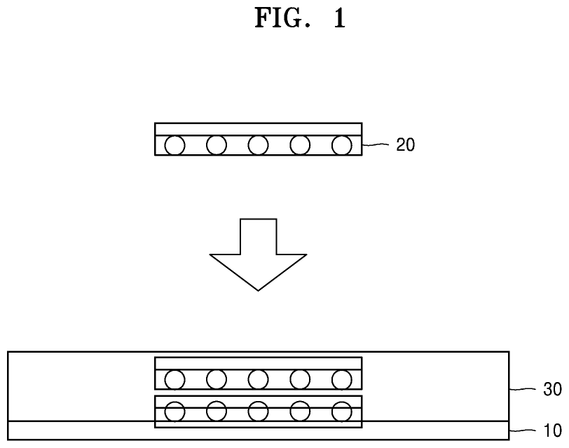

FIG. 2 illustrates a flowchart of a chip packaging method based on a panel form according to an example embodiment of the present disclosure.

FIG. 3 illustrates a step of a chip packaging method based on a panel form according to an example embodiment of the present disclosure.

FIG. 4 illustrates a step of the chip packaging method based on the panel form according to an example embodiment of the present disclosure.

FIG. 5 illustrates a step of the chip packaging method based on the panel form according to an example embodiment of the present disclosure.

FIG. 6 illustrates a flowchart of a method of preparing a plurality of chip package units according to an example embodiment of the present disclosure.

FIG. 7 illustrates a step of a method of preparing a plurality of chip package units according to an example embodiment of the present disclosure.

FIG. 8 illustrates a step of the method of preparing the plurality of chip package units according to an example embodiment of the present disclosure.

FIG. 9 illustrates a step of the method of preparing the plurality of chip package units according to an example embodiment of the present disclosure.

FIG. 10 illustrates a step of the method of preparing the plurality of chip package units according to an example embodiment of the present disclosure.

FIG. 11 illustrates a chip package according to an example embodiment of the present disclosure.

### DETAILED DESCRIPTION

Hereinafter, various non-limiting example embodiments of the present disclosure will be described more fully with reference to the drawings, in which certain embodiments are illustrated. Embodiments of the present disclosure may, however, be embodied in many different forms, and should not be interpreted as being limited to the example embodiments set forth herein. Rather, these example embodiments are provided such that the description will be thorough and complete, and will convey the scope of the present disclosure to those skilled in the art. In the drawings, sizes of layers and regions may be exaggerated for sake of clarity.

For ease of description, spatially relative terms, such as “beneath,” “below,” “lower,” “above,” “upper,” and the like, may be used herein to describe one element's relationship to other elements as illustrated in the drawings. It will be understood that the spatially relative terms are also intended to encompass different orientations of a device in use or operation, in addition to the orientation(s) depicted in the drawings. For example, if the device in the drawings is turned over, an element described as “below” or “beneath” other elements would then be oriented “above” the other elements. Thus, the term “below” can encompass an orientation of both “above” and “below”. The device may be otherwise oriented (e.g., rotated 90 degrees or at other orientations), and the spatially relative descriptors used herein are interpreted accordingly.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element or layer is referred to as being “directly over,” “directly above,” “directly on,” “directly below,” “directly under,” “directly beneath,” “directly connected to” or “directly coupled to” another element or layer, there are no intervening elements or layers present.

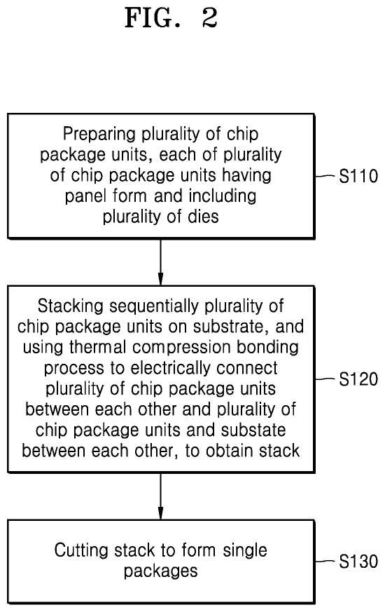

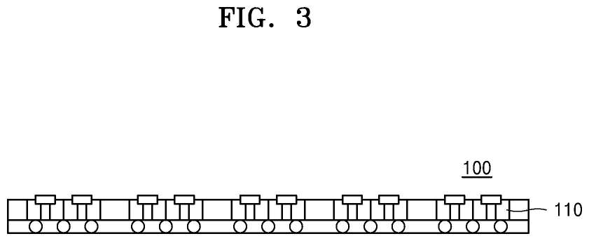

FIG. 2 illustrates a flowchart of a chip packaging method based on a panel form according to an example embodiment of the present disclosure. FIGS. 3, 4, and 5 illustrate respective steps of a chip packaging method based on a panel form according to an example embodiment of the present disclosure.

Referring to FIGS. 2 and 3, a chip packaging method according to an example embodiment of the present disclosure may include, in a step S110, preparing a plurality of chip package units 100. Each of the plurality of chip package units 100 has a panel form and includes a plurality of dies 110.

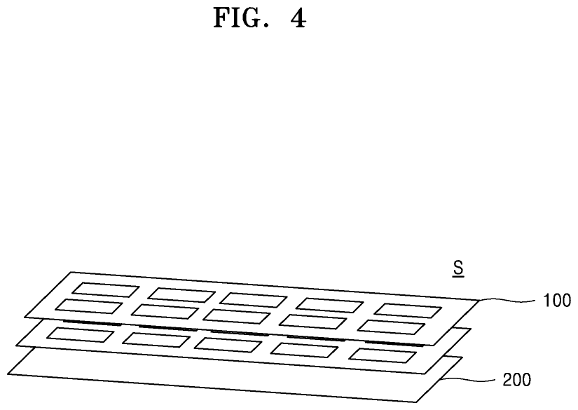

Next, referring to FIGS. 2 and 4, in a step S120, the plurality of chip package units 100 are sequentially stacked on a substrate 200, and a thermal compression bonding process is used to electrically connect the plurality of chip package units 100 to each other and electrically connect the plurality of chip package units 100 and the substrate 200 to each other, to obtain a stack S.

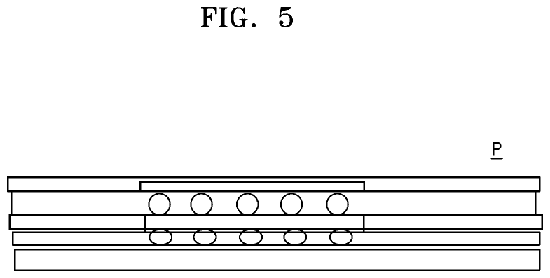

Next, referring to FIGS. 2 and 5, in a step S130, the stack S is cut to form single packages P.

In an embodiment, the substrate 200 may be a printed circuit board, a ceramic substrate, or an interposer layer, or may also be a substrate of any material that is commonly used in the art to form a semiconductor package. The thermal compression bonding (TCB) process as described herein may be a packaging process commonly used in the art, i.e., a process of bonding dies having flip-chip structures to each other by heating and compressing. In the related art, a chip-to-chip TCB method is generally used. This method may cause a low production efficiency due to a long bonding time.

A chip packaging method according to an example embodiment of the present disclosure uses chip package units having panel forms to form a stack, and may achieve a bonding of multiple chips in one TCB process, which significantly improves a production efficiency.

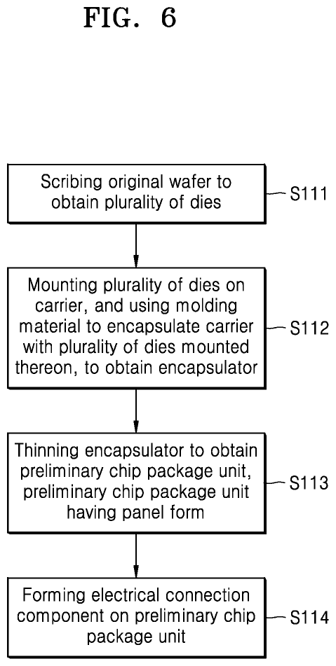

Below, a method of preparing a plurality of chip package units 100 illustrated in FIGS. 2 and 3 will be described in detail with reference to FIGS. 6-10.

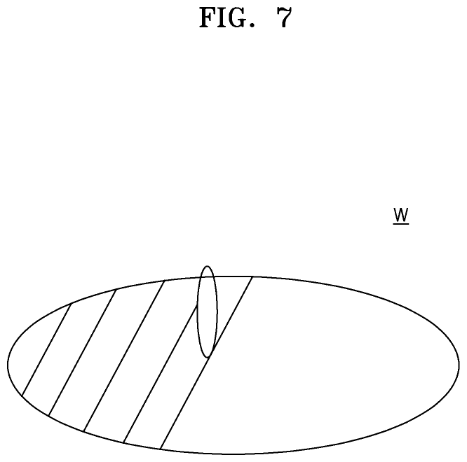

FIG. 6 illustrates a flowchart of a method of preparing a plurality of chip package units according to an example embodiment of the present disclosure. FIGS. 7, 8, 9, and 10 illustrate respective steps of a method of preparing a plurality of chip package units according to an example embodiment of the present disclosure.

Referring to FIGS. 6 and 7, in an embodiment, the step S110 of preparing the plurality of chip package units 100 as illustrated in FIG. 2 may include, in a step S111, scribing an original wafer W to obtain a plurality of dies 110.

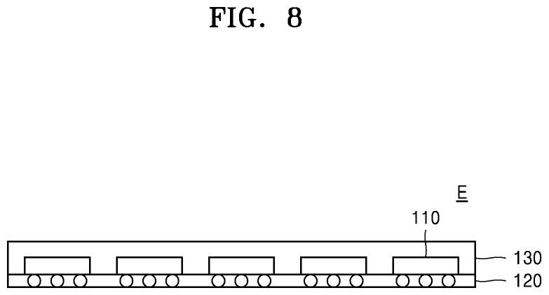

Next, referring to FIGS. 6 and 8, in a step S112, the plurality of dies 110 are mounted on a carrier 120, and a molding material 130 is used to encapsulate the carrier 120 with the plurality of dies 110 mounted thereon, to obtain an encapsulator E.

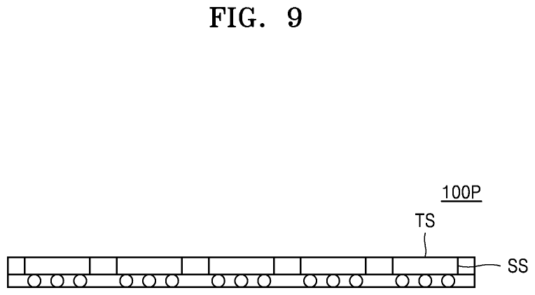

Next, referring to FIGS. 6 and 9, in a step S113, the encapsulator E is thinned to obtain a preliminary chip package unit 100P. The preliminary chip package unit 100P has a panel form.

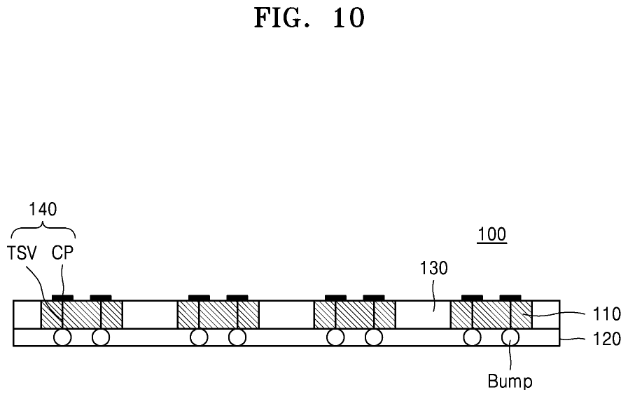

Finally, referring to FIGS. 6 and 10, in a step S114, an electrical connection component 140 is formed on the preliminary chip package unit 100P. After the electrical connection component 140 is formed, the preliminary chip package unit 100P may be formed as a chip package unit 100.

In an embodiment, the electrical connection component 140 may include through silicon vias TSV and contact pads CP. When the plurality of chip package units 100 are sequentially stacked on a substrate 200 (see FIG. 4), the plurality of chip package units 100 may communicate between each other and between them and the substrate 200 via the through silicon vias TSV and the contact pads CP. However, the electrical connection component is not limited thereto.

Referring back to FIG. 9, in an embodiment, the step S113 of thinning the encapsulator E may include partially removing the molding material 130 to expose top surfaces TS of the plurality of dies 110, such that the remaining molding material 130 covers side surfaces SS of each of the plurality of dies 110. However, embodiments of the present disclosure are not limited thereto, and the molding material may also be thinned until just covering the top surfaces of the plurality of dies.

In the related art, generally, an original wafer is thinned at first, and then the thinned wafer is scribed to be divided and cut into a plurality of dies, and then the plurality of dies are mounted on a carrier and are encapsulated. In this case, a chip crack, a chipping, and/or a single-chip warpage may be easily caused in a cutting process by the thinned chip due to a thin thickness thereof, thereby causing a low mounting quality, and a low efficiency of a thermal compression bonding process subsequently performed.

According to a chip packaging method according to an example embodiment of the present disclosure, when preparing a plurality of chip package units, a scribing process is performed at first on an original wafer, and a thinning process is then performed on an encapsulator including a plurality of dies and a molding material, so that a chip damage occurring in cutting a thin wafer may be prevented.

Referring to FIG. 10, in an embodiment, the carrier 120 may include a non-conductive film (NCF) or a non-conductive paste (NCP) as an under-fill material. Here, by, for example, a spin coating process, the NCP may be applied at a die level to, for example, a semiconductor die with conductive bumps thereon, and positioned on an active surface of the semiconductor die and over the bumps, or applied at a wafer level to a non-scribed semiconductor die array. The NCF may be applied at a wafer level to a semiconductor die with conductive bumps thereon by, for example, a film lamination process.

In this embodiment, each of the plurality of chip package units 100 may be configured as a substrate structure formed of the plurality of dies 110, the molding material 130, and the NCF. As illustrated in FIG. 10, the substrate structure may have a panel form.

Referring to FIG. 4 together with FIG. 10, after the plurality of chip package units 100 are sequentially stacked on the substrate 200, a thermal compression bonding process may be performed by applying heat and pressure. When the heat and the pressure are applied, the NCF may be melted and flow to fill under-spaces of the plurality of chip package units 100.

In this embodiment, the above-described substrate structure having the panel form may be used as a barrier layer in the thermal compression bonding process. The barrier layer may prevent an excessive amount of the under-fill material from overflowing from between the plurality of chip package units 100 stacked, that is, prevent an occurrence of a NCF fillet, thereby improving a reliability of a semiconductor package.

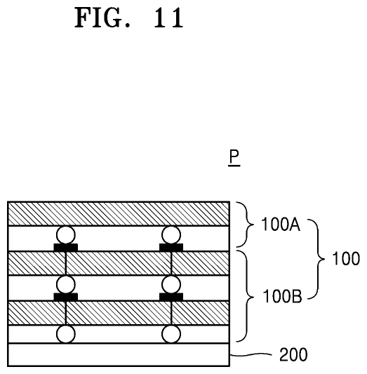

Hereinafter, a chip package manufactured according to a chip packaging method based on a panel form illustrated in FIG. 2 will be described in detail with reference to FIG. 11.

FIG. 11 illustrates a chip package according to an example embodiment of the present disclosure. As illustrated in FIG. 11, a chip package P includes a substrate 200 and a plurality of chip package units 100 sequentially stacked on the substrate 200. Each of the plurality of chip package units 100 has a panel form. Although not entirely illustrated in FIG. 11, each of the plurality of chip package units 100 may include a carrier 120, a plurality of dies 110 mounted on the carrier 120, and an encapsulation layer formed of a molding material 130, as described with reference to FIGS. 8-10 above. The encapsulation layer at least covers a side surface SS of each of the plurality of dies 110. In addition, by using a thermal compression bonding process, the plurality of chip package units 100 are electrically connected to each other, and the plurality of chip package units 100 and the substrate 200 are electrically connected to each other.

In an embodiment, the plurality of dies 110 included in each of the plurality of chip package units 100 may be configured to be thinned after undergoing a scribing process, a mounting process, and an encapsulating process, which may prevent a chip damage that occurs in cutting a thin wafer.

In an embodiment, each of the plurality of chip package units 100 may include through silicon vias TSV and contact pads CP as an electrical connection component, and the carrier 120 may include a non-conductive film (NCF) or a non-conductive paste (NCP) as an under-fill material.

In an embodiment, the plurality of chip package units 100 may include an uppermost chip package unit 100A and chip package units 100B disposed and stacked between the uppermost chip package unit 100A and the substrate 200. In this embodiment, the uppermost chip package unit 100A may not have a TSV structure.

In a chip package according to an example embodiment of the present disclosure, a plurality of dies are fixed by a frame formed of a molding material to form a substrate structure having a panel form. By a substrate-to-substrate direct bonding, an efficiency of a thermal compression bonding (TCB) process may be improved. Furthermore, in a process of forming a chip package unit, cutting may be formed on a wafer having an initial thickness, such that a chip damage occurring in a conventional cutting for 3D TSV chips may be prevented. Furthermore, in a thermal compression bonding process, an occurrence of a NCF fillet may be effectively prevented by using a substrate structure itself as a barrier layer.

While non-limiting example embodiments of the present disclosure have been illustrated and described herein, it will be apparent to those skilled in the art that various modifications and variations may be made without departing from the spirit and scope of the present disclosure.

What is claimed is:

1. A chip packaging method comprising:
preparing a plurality of chip package units, each of the plurality of chip package units having a panel form and including a plurality of dies;
sequentially stacking the plurality of chip package units on a substrate, and using a thermal compression bonding process to electrically connect the plurality of chip package units to each other and electrically connect the plurality of chip package units and the substrate to each other, to obtain a stack; and
cutting the stack to form single packages.

2. The chip packaging method as claimed in claim 1, wherein the preparing of the plurality of chip package units comprises, for each chip package unit from among the plurality of chip package units:
scribing an original wafer to obtain the plurality of dies that correspond to the chip package unit;
mounting the plurality of dies that correspond to the chip package unit on a carrier, and using a molding material to encapsulate the plurality of dies that are mounted on the carrier, to obtain an encapsulator;
thinning the encapsulator to obtain a preliminary chip package unit, the preliminary chip package unit having the panel form; and
forming an electrical connection component on the preliminary chip package unit.

3. The chip packaging method as claimed in claim 2, wherein the electrical connection component includes through silicon vias and contact pads.

4. The chip packaging method as claimed in claim 3, wherein the carrier includes a non-conductive film or a non-conductive paste as an under-fill material.

5. The chip packaging method as claimed in claim 4, wherein each of the plurality of chip package units is configured as a substrate structure formed of the plurality of dies, the molding material, and the non-conductive film, and
wherein the substrate structure has the panel form.

6. The chip packaging method as claimed in claim 5, wherein the substrate structure is configured to be used as a barrier layer in the thermal compression bonding process.

7. The chip packaging method as claimed in claim 2, wherein the thinning of the encapsulator comprises:
partially removing the molding material to expose top surfaces of the plurality of dies, such that remaining portions of the molding material are provided on side surfaces of each of the plurality of dies.

8. The method as claimed in claim 2, wherein the thinning of the encapsulator comprises partially removing the molding material such that the molding material remains on top surfaces of the plurality of dies.

9. A chip package, comprising:
a substrate; and
a plurality of chip package units sequentially stacked on the substrate, each of the plurality of chip package units having a panel form,
wherein each chip package unit from among the plurality of chip package units comprises:
a carrier;
a plurality of dies mounted on the carrier; and
an encapsulation layer, formed of a molding material, on side surfaces of each of the plurality of dies, and
wherein the plurality of chip package units are electrically connected to each other and are electrically connected to the substrate by a thermal compression bonding process.

10. The chip package as claimed in claim 9, wherein the plurality of dies included in each of the plurality of chip package units are configured to be thinned after undergoing a scribing process, a mounting process, and an encapsulating process.

11. The chip package as claimed in claim 9, wherein
each of the plurality of chip package units further comprises through silicon vias and contact pads as an electrical connection component, and
the carrier comprises a non-conductive film or a non-conductive paste as an under-fill material.

12. The chip package as claimed in claim 9, wherein at least two of the plurality of chip package units further comprises through silicon vias and contact pads as an electrical connection component, and
wherein the carrier comprises a non-conductive film or a non-conductive paste as an under-fill material.

13. The chip package as claimed in claim 9, wherein an uppermost one of the plurality of chip package units does not include a through silicon via.

14. A method of preparing a chip package unit, the method comprising:
scribing an original wafer to obtain a plurality of dies;
mounting the plurality of dies on a carrier, and using a molding material to encapsulate the plurality of dies that are mounted on the carrier, to obtain an encapsulator;
thinning the encapsulator to obtain a preliminary chip package unit, the preliminary chip package unit having a panel form; and
obtaining the chip package unit, the obtaining comprising forming an electrical connection component on the preliminary chip package unit.

15. The method as claimed in claim 14, wherein the electrical connection component includes through silicon vias and contact pads.

16. The method as claimed in claim 15, wherein the carrier includes a non-conductive film or a non-conductive paste as an under-fill material.

17. The method as claimed in claim 16, wherein the chip package unit is configured as a substrate structure formed of the plurality of dies, the molding material, and the non-conductive film, and
wherein the substrate structure has the panel form.

18. The method as claimed in claim 17, wherein the substrate structure is configured to be used as a barrier layer in a thermal compression bonding process.

19. The method as claimed in claim 14, wherein the thinning of the encapsulator comprises:
partially removing the molding material to expose top surfaces of the plurality of dies, such that remaining portions of the molding material are provided on side surfaces of each of the plurality of dies.

20. The method as claimed in claim 14, wherein the thinning of the encapsulator comprises partially removing the molding material such that the molding material remains on top surfaces of the plurality of dies.
